(19) United States
(12) Patent Application Publication
(10) Pub. No.: US 2024/0194448 A1
(43) Pub. Date: Jun. 13, 2024

(54) ATOMIC LAYER DEPOSITION DEVICE USING MULTIPLE PULSES TO FILL GAP OF SEMICONDUCTOR STRUCTURE WITH HIGH ASPECT RATIO AND ATOMIC LAYER DEPOSITION METHOD USING THE SAME

(71) Applicant: RESEARCH & BUSINESS FOUNDATION SUNGKYUNKWAN UNIVERSITY, Suwon-si (KR)

(72) Inventors: Geun Young YEOM, Seoul (KR); Ho Gon KIM, Hwaseong-si (KR); Hyun Woo TAK, Yongin-si (KR); Jong Woo HONG, Goyang-si (KR); Ji Eun KANG, Yongin-si (KR)

(73) Assignee: RESEARCH & BUSINESS FOUNDATION SUNGKYUNKWAN UNIVERSITY, Suwon-si (KR)

(21) Appl. No.: 18/534,250

(22) Filed: Dec. 8, 2023

(30) Foreign Application Priority Data
Dec. 9, 2022 (KR) 10-2022-0172075

(51) Int. Cl. H01J 37/32; C23C 16/455; H01L 21/02

(52) U.S. Cl. CPC H01J 37/32183; C23C 16/45538; H01J 37/3244; H01L 21/02274; H01L 21/0228; H01J 2237/332; H01L 21/0214; H01L 21/02164; H01L 21/0217

(57) ABSTRACT

One embodiment of the present invention provides an atomic layer deposition device for filling a gap of a semiconductor structure with a high aspect ratio and a method of manufacturing the same. According to the atomic layer deposition method of filling the gap of the semiconductor structure with the high aspect ratio according to one embodiment of the present invention, it is possible to remove an overhang at an pattern top at the same time as deposition and perform the gap-filling to remove a void and a seam by improving bottom-up deposition in a high aspect ratio structure of 40:1 or more.

### CROSS REFERENCE TO RELATED APPLICATION

The present application claims priority to Korean Patent Application No. 10-2022-0172075, filed Dec. 9, 2022, the entire contents of which is incorporated herein for all purposes by this reference.

### BACKGROUND OF THE INVENTION

### Field of the Invention

The present invention relates to an atomic layer deposition device for filling a gap of a semiconductor structure with a high aspect ratio, and more specifically, to an atomic layer deposition method of filling a gap of a semiconductor structure with a high aspect ratio by controlling the ON-OFF of pulsed source RF power and pulsed bias RF power.

### Description of the Related Art

With the demand for high-performance and high-capacity semiconductor devices, a structure is changing from a 2 dimension (2D) to a three dimension (3D), a size of the device is decreasing, and a height of the device is further increasing.

Therefore, a pattern structure has a high aspect ratio structure. In the high aspect ratio structure, a separation process for separating cells that are transistor arrays is becoming more important.

A silicon dioxide (SiO₂) material with excellent dielectric characteristics is used in the separation process and is filled in the high aspect ratio structure. This is called a gap-filling process.

However, when gap-filling is performed on the high aspect ratio structure using conventional methods, a void or a seam may be formed inside the structure, which causes defects that degrade device performance. The formation of the void and the seam is known as being caused by an overhang formed at pattern top of the high aspect ratio structure.

There are conventionally various technologies for the gap-filling of the high aspect ratio structure. There are a spin-coating method using a liquid source, a flowable deposition (F-CVD) using the fluidity characteristics of a precursor, and an atomic layer deposition (ALD). In this case, the ALD includes a thermal method and a method using plasma.

In this case, the spin-coating method subsequently requires a high-temperature steam heat treatment process at 800° C. or higher in order to obtain silicon oxide (SiO₂) with excellent dielectric characteristics after depositing the liquid source on a wafer surface. This high-temperature heat treatment process causes the degradation of the device performance in three-dimensional high aspect ratio structures.

In addition, the F-CVD method forms silicon oxide (SiO₂) with excellent dielectric characteristics through a subsequent curing process after performing gap-filling using the fluid precursor. In this case, the curing process requires a high-temperature heat treatment process of 700° C. or higher, which causes the degradation of the device performance.

In addition, the ALD uses an atomic layer deposition method and includes a thermal ALD and a plasma enhanced ALD (PE-ALD). The thermal method also requires a high-temperature process, and the PE method allows a relatively lower temperature process, but has a problem in that an overhang is formed at pattern top of the high aspect ratio structure.

This causes the formation of a void or a seam inside the structure, and the overhang is formed by a faster deposition rate at the pattern top than a deposition rate at a bottom or side-wall of the structure.

In this case, the reason why the deposition rate is faster is that concentrations of reactive species such as ions and radicals used in reaction are high. In order to solve such an overhang problem, an additional process of repeatedly performing deposition-etching-deposition is required, and a low throughput due to this results in low productivity.

Therefore, many challenges still remain to fill the gap of the semiconductor structure with the high aspect ratio.

### SUMMARY OF THE INVENTION

The present invention is directed to providing an atomic layer deposition device for filling a gap of a semiconductor structure with a high aspect ratio and a method of manufacturing the same.

The object of the present invention are not limited to the above-described object, and other objects that are not mentioned will be able to be clearly understood by those skilled in the art to which the present invention pertains from the following description.

In order to achieve the object, one embodiment of the present invention provides an atomic layer deposition method of filling a gap of a semiconductor structure with a high aspect ratio.

The atomic layer deposition method of filling the gap of the semiconductor structure with the high aspect ratio includes a first operation of putting a substrate on which a high aspect ratio structure is formed into a reaction chamber, a second operation of injecting a precursor gas into the substrate on which the high aspect ratio structure is formed and adsorbing the precursor gas onto the substrate, a third operation of supplying a process gas to an inside of the chamber, generating plasma in a reaction space above the substrate by applying pulsed or non-pulsed source RF power, and applying pulsed bias RF power, and a fourth operation of controlling the ON-OFF of the pulsed or non-pulsed source RF power and the pulsed bias RF power.

In addition, according to one embodiment of the present invention, the method may further include a purging operation between the second operation and the third operation.

In addition, according to one embodiment of the present invention, in the fourth operation, the pulsed or non-pulsed source RF power may be continuously applied at the same power, and the pulsed bias RF power may be applied in ON-OFF states.

In addition, according to one embodiment of the present invention, when the pulsed bias RF power is turned on or off, a pulse duty ratio is in a range of 1 to 100%. In addition, a pulse frequency may be in a range of 500 Hz to 50 KHz.

In addition, according to one embodiment of the present invention, in the fourth operation, the pulsed or non-pulsed source RF power may be continuously applied at the same intensity, and the pulsed bias RF power may be continuously applied and may have an adjustable intensity.

In addition, according to one embodiment of the present invention, in the fourth operation, the pulsed or non-pulsed source RF power may be continuously applied and may have an adjustable intensity, and the pulsed bias RF power may be continuously applied and may have an adjustable intensity.

In addition, according to one embodiment of the present invention, in the fourth operation, the pulsed or non-pulsed source RF power may be applied in ON-OFF states, and the pulsed bias RF power may be applied in ON-OFF states.

In addition, according to one embodiment of the present invention, in the fourth operation, the pulsed or non-pulsed source RF power and the pulsed bias RF power may be simultaneously applied and simultaneously cut off.

In addition, according to one embodiment of the present invention, in the fourth operation, when the pulsed or non-pulsed source RF power is applied, the pulsed bias RF power may be cut off, and when the pulsed source RF power is cut off, the pulsed bias RF power may be applied.

In addition, according to one embodiment of the present invention, the bias RF power may be applied in a range of 5 to 500 W.

In addition, according to one embodiment of the present invention, in the fourth operation, when a deposit generated by a deposition process gas is filled inside the high aspect ratio structure, the application of the pulsed source RF power and the pulsed bias RF power may be stopped.

In addition, according to one embodiment of the present invention, in the third operation, power may be applied by further including an additional power supply other than the bias RF power.

In addition, according to one embodiment of the present invention, the atomic layer deposition method of filling the gap of the semiconductor structure with the high aspect ratio may be performed at a temperature of 0 to 500° C.

In order to achieve the object, another embodiment of the present invention provides an atomic layer deposition device for filling a gap of a semiconductor structure with a high aspect ratio.

An atomic layer deposition device for filling a gap of a semiconductor structure with a high aspect ratio according to one embodiment of the present invention includes a reaction chamber in which a constant reaction space is formed, a substrate mounting table which is installed inside the reaction chamber and on which a substrate is placed, a gas spray unit configured to spray a precursor and a process gas onto the substrate mounting table, a source RF plasma generation unit installed above the reaction chamber and connected to the gas spray unit, a bias RF power source unit installed under the reaction chamber, connected to the substrate mounting table, and configured to supply bias RF power, and a control unit configured to control the ON-OFF of source RF power of the source RF plasma generation unit and bias RF power of the bias RF power source unit.

In addition, according to one embodiment of the present invention, the source RF plasma generation unit may include an RF power source configured to supply impedance-matched RF power to a plasma generation source, and a pulse RF connected between a gas supplier and the RF power source.

In addition, according to one embodiment of the present invention, the bias RF power source unit may include a bias RF power source configured to supply impedance-matched bias RF power to the substrate mounting table, and a pulse RF connected between the substrate mounting table and the bias RF power source.

### BRIEF DESCRIPTION OF THE DRAWINGS

FIG. 1 is a flowchart illustrating an atomic layer deposition method of filling a gap of a semiconductor structure with a high aspect ratio according to one embodiment of the present invention;

FIG. 2 is a schematic diagram illustrating an atomic layer deposition device for filling the gap of the semiconductor structure with the high aspect ratio according to one embodiment of the present invention.

FIG. 3 is a schematic diagram illustrating a result deposited by the atomic layer deposition method of filling the gap of the semiconductor structure with the high aspect ratio according to one embodiment of the present invention.

FIG. 4 is scanning electron microscope (SEM) images representing a result of Experimental Example 1.

FIG. 5 is scanning electron microscope (SEM) images representing a result of Experimental Example 2.

FIG. 6 is a graph illustrating a result of Example 1.

FIG. 7 is a graph illustrating a result of Example 2.

FIG. 8 is a graph illustrating a result of Example 3.

FIG. 9 is a graph illustrating a result of Example 4.

FIG. 10 is a graph illustrating a result of Example 5.

FIG. 11 is a graph illustrating a result of Example 6.

FIG. 12 is a graph illustrating a result of Example 7.

FIG. 13 is a graph illustrating a result of Example 8.

FIG. 14 is a graph illustrating a result of Example 9.

FIG. 15 is a graph illustrating a result of Example 10.

FIG. 16 is a graph illustrating a result of Example 11.

FIG. 17 is a graph illustrating a result of Example 12.

FIG. 18 is a graph illustrating a result of Example 13.

FIG. 19 is a graph illustrating a result of Example 14.

FIG. 20 is a graph illustrating a result of Example 15.

FIG. 21 is a graph illustrating a result of Example 16.

FIG. 22 is a graph illustrating a result of Example 17.

FIG. 23 is a graph illustrating a result of Example 18.

FIG. 24 is a graph illustrating a result of Example 19.

FIG. 25 is a graph illustrating a result of Example 20.

FIG. 26 is a graph illustrating a result of Example 21.

### DETAILED DESCRIPTION OF THE INVENTION

Hereinafter, the present invention will be described with reference to the accompanying drawings. However, the present invention may be implemented in various different forms and is not limited to embodiments described herein. In addition, in order to clearly describe the present invention in the drawings, components irrelevant to the description have been omitted, and throughout the specification, similar components have been denoted by similar reference numerals.

Throughout the specification, when a first component is described as being “connected to (joined to, in contact with, or coupled to)” a second component, this includes not only a case in which the first component is “directly connected” to the second component, but also a case in which the first component is “indirectly connected” to the second component with a third component interposed therebetween. In addition, when the first component is described as “including,” the second component, this means that the first component may further include the third component rather than precluding the third component unless especially stated otherwise.

The terms used in the specification are only used to describe specific embodiments and are not intended to limit the present invention. The singular expression includes the plural expression unless the context clearly dictates otherwise. In the specification, it should be understood that terms such as “comprise” or “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

Hereinafter, embodiments of the present invention will be described in detail with reference to the accompanying drawings.

An atomic layer deposition method of filling a gap of a semiconductor structure with a high aspect ratio according to one embodiment of the present invention will be described.

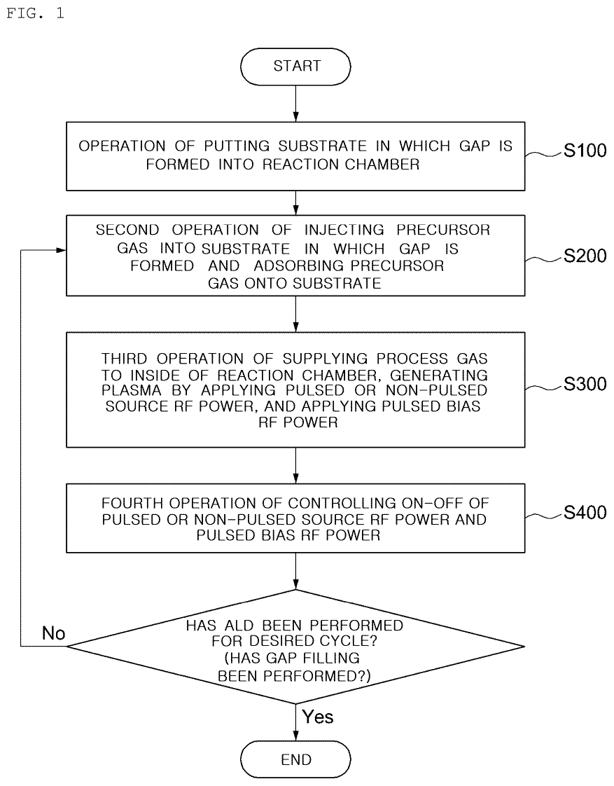

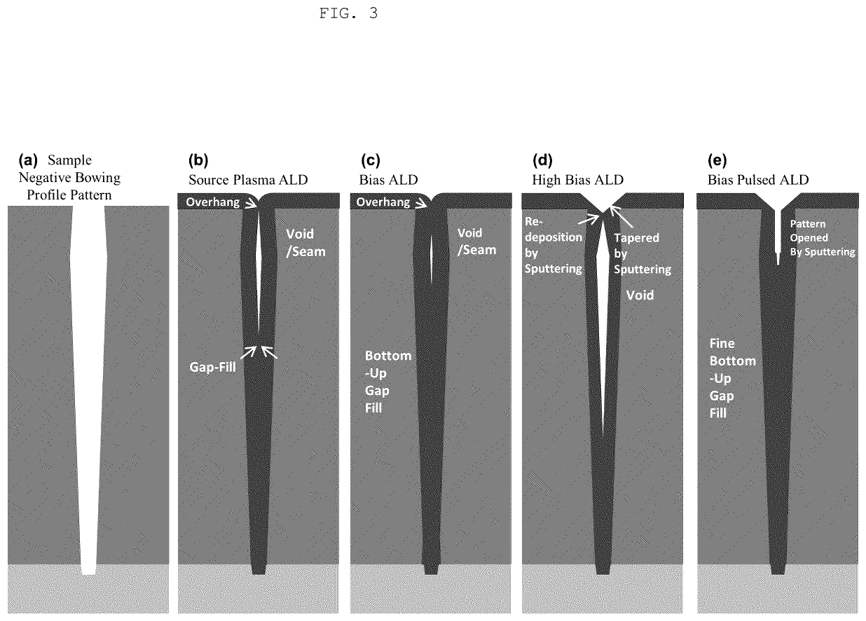

The atomic layer deposition method of filling the gap of the semiconductor structure with the high aspect ratio will be described with reference to FIGS. 1 and 3.

FIG. 1 is a flowchart illustrating an atomic layer deposition method of filling a gap of a semiconductor structure with a high aspect ratio according to one embodiment of the present invention.

Referring to FIG. 1, the atomic layer deposition method of filling the gap of the semiconductor structure with the high aspect ratio according to one embodiment of the present invention may include a first operation of putting a substrate in which a gap of a high aspect ratio structure is formed into a reaction chamber (S100), a second operation of injecting a precursor gas into the substrate in which the gap is formed and adsorbing the precursor gas onto the substrate (S200), a third operation of supplying a process gas to an inside of the reaction chamber, generating plasma in a reaction space above the substrate by applying pulsed or non-pulsed source RF power, and applying pulsed bias RF power (S300), and a fourth operation of controlling the ON-OFF of the pulsed or non-pulsed source RF power and the pulsed bias RF power (S400).

In this case, a determined ALD cycle process may be repeatedly performed until the gap is filled.

In addition, the method may further include an operation of purging the chamber between the second operation and the third operation.

In addition, after the fourth operation, the method may further include an operation of finishing plasma reaction with a surface onto which the precursor gas is adsorbed and purging the chamber.

An atomic layer deposition (ALD) is a nano-thin film deposition technology using a phenomenon in which a single atomic layer is chemically attached and has characteristics in which, since oxide or metal thin films may be deposited on a substrate in a unit of an atomic layer, the compositions of atoms may be changed to a relatively smaller thickness and laminated.

In the ALD process, a surface environment of the substrate is adjusted step by step to form a self-saturated unit atomic film raw material, and reaction occurs on a surface thereof. Due to the characteristic that the self-saturated raw material is formed, the ALD may have an adjustable thickness in a unit of atom and deposit a conformal thin film even when a surface with a complicated shape is formed by a surface movement of a raw material precursor. In addition, the ALD has an advantage in that it is possible to minimize the formation of particles due to the minimization of gas phase reaction, a density of the deposited thin film may be high, and a deposition temperature may be decreased.

In a first stage, the method may include a first operation of putting a substrate in which a gap is formed into a reaction chamber (S100).

The present invention has been described that an aspect ratio of a pattern of the substrate is, for example, 40:1, but is not necessarily limited thereto, and may also be sufficiently applied to a high aspect ratio of 30:1˜100:1.

In addition, the present invention is characterized in that a gap of a substrate in which the gap of a nm-level pattern with 10 to 200 nm in size is formed may be filled and may also be applied to a gap beyond 10 to 200 nm in size without limitation.

In a second stage, the method may include a second operation of injecting a precursor gas into the substrate in which the gap is formed and adsorbing the precursor gas onto the substrate (S200).

Since the injected precursor gas in the present invention may include one or more selected from the group of Si-containing Si precursors such as silane, TEOS, DIPAS, BDEAS, TDMAS, DCS, BTBAS, 3DMAS, TSA, NPS, DSBAS, PCDS or HCDS and vary depending on the type of a material layer to be deposited, the present invention is not limited to the above-described example.

For example, the precursor may be DIPAS. When the precursor is DIPAS, a SiO₂ thin film may be formed by the atomic layer deposition method when one or more selected from the group of reactive gases formed by containing oxygen, such as O₂, NO, N₂O, and H₂O.

In addition, for example, a precursor gas containing metal-based precursors such as tungsten (W) and titanium (Ti) or dielectric-based precursors such as hafnium (Hf) may be included.

When the precursor is deposited on a surface of a metal powder as an atomic layer, the precursor no longer reacts even when a large amount of the precursor is supplied due to self-limiting reaction.

In addition, the method may include a purging operation of discharging non-adsorbed precursor by injecting an inert gas after the precursor is adsorbed.

The inert gas may be a gas such as argon (Ar), nitrogen (Ne), or helium (He), but is not limited thereto.

For example, the inert gas may be argon (Ar).

The argon gas may be, for example, injected at a rate of 30 sccm for 10 seconds.

Precursor materials not chemically adsorbed may be removed by performing purging using the inert gas.

In the third stage, the method may include the third operation of supplying a process gas to an inside of the chamber, generating plasma in a reaction space above the substrate by applying pulsed or non-pulsed source RF power, and applying pulsed bias RF power (S300).

The process gas may vary depending on the type of the material layer to be deposited.

For example, as an example of the process gas used in the process of the present invention, a process gas in an oxide film (SiO₂ film) process may include one or more selected from the group of gases containing oxygen, such as O₂, NO, N₂O, and H₂O, but any material containing oxygen and having the characteristics that an oxide film may be formed may be used.

In addition, a process gas in a nitride film (SiₓN_{y}) process may include one or more gases selected from the group of gases containing nitrogen, such as N₂, NO, N₂O, and NH₃, but any material containing nitrogen and having the characteristic that a nitride film may be formed may be used.

Therefore, since the process gas varies depending on the type of the material layer to be deposited, the present invention is not limited to the above-described example.

In this case, in the present invention, in the case of a process using a Si-based precursor, the process gas may be O₂ or NH₃, and when the process gas is O₂, a SiO₂ thin film may be formed by the atomic layer deposition method, and when the process gas is NH₃, a Si₃N₄ thin film may be formed by the atomic layer deposition method.

In addition, in some cases, other elements that may obtain the effect of a mixed gas may be contained.

For example, in the case of the process using the Si-based precursor, when a thin film such as SiON is deposited, one or more selected from the group of oxygen-containing gases such as O₂, NO, N₂O, and H₂O may be included, and at the same time, nitrogen-containing gases such as NH₃, N₂, NO, and N₂O may be contained and mixed or added.

In addition, inert gases such as He, Ne, Ar, Kr, and Xe may be contained as an assist for assisting with generating plasma. The inert gas may be accompanied by the sputtering effect and may assist the effect thereof.

In this case, it is characterized that pulsed or non-pulsed source RF power according to one embodiment of the present invention may be applied and generates plasma in the reaction space above the substrate.

In addition, the source RF power may be applied by equipment including RF power (source) capable of generating plasma and RF power (bias) capable of generating a negative direct current (DC) through a supplied RF.

In this case, the RF power (source) may have the form of capacitively coupled plasma (CCP) and inductively coupled plasma (ICP) and may be a plasma source in other forms of microwave plasma and ECR plasma, which may generate plasma.

In this case, in the case of the form of the CCP, the RF power (source) may have a form in which a power supply is connected to an electrode such as the RF power (bias).

In addition, the RF power (source) may be used in various structures capable of generating plasma and is not limited thereto, such as including the form of pulsed plasma.

In addition, according to the present invention, the source RF power and the bias power (bias source including RF, DC or DC pulsed) may be applied at the same time.

The pulsed bias power may be supplied to the substrate.

In this case, by pulsing the bias power, reactive ions may be efficiently supplied to a bottom of the high aspect ratio structure due to reduced charging during a pulse OFF.

In addition, the pulsing increases the diffusion of radical reaction species, and thus by decreasing a difference in deposition rates of pattern top and a bottom of the high aspect ratio structure, it is possible to prevent the formation of an overhang.

In addition, due to the biasing effect, the pattern top of the high aspect ratio is sputtered, and thus the enlargement of the pattern top opening may be kept constant.

Therefore, bottom-up deposition in which deposition is performed from the bottom and the top of the high aspect ratio structure may be possible.

In this case, a frequency of the RF power (source) and a frequency of the RF power (bias) may be in a range of 400 kHz to 300 MHz, and when the RF power (source) and the RF power (bias) function to generate plasma and generate a bias, respectively, the frequencies thereof are not limited.

However, for example, when the frequency of the RF power (source) that functions to generate plasma has the form of the CCP, relatively higher frequencies of 13.56 MHz, 27.12 MHz, 60 MHz, and 100 MHz may be preferred, and in the case of the frequency of the RF power (bias), relatively lower frequencies of 400 kHz, 2 MHz, and 13.56 MHz may be preferred.

In addition, the present invention is characterized that an additional pulsed power supply other than the source and bias power supplies may be combined, which is not necessarily limited to the RF power supply and is combined with related power supplies that may change a plasma state to obtain the effects.

In a fourth stage, the method may include a fourth operation of controlling the ON-OFF of the pulsed or non-pulsed source RF power and the pulsed bias RF power (S400).

The present invention may propose various pulsing techniques by controlling ON-OFF states of the pulsed or non-pulsed source RF power and the pulsed bias RF power.

For example, when the pulsed or non-pulsed source RF power is continuously applied at the same intensity, the pulsed bias RF power is applied in ON-OFF states, and the pulsed source RF power is cut off, the pulsed bias RF power may or may not be cut off simultaneously.

In addition, when the pulsed or non-pulsed source RF power is applied in the ON-OFF states, the pulsed bias RF power is applied in ON-OFF states, and the pulsed source RF power is cut off, the pulsed bias RF power may or may not be cut off simultaneously.

In addition, according to one embodiment of the present invention, power may be applied by further including a power supply capable of simultaneously obtaining the effect of different frequencies from the source RF power or the bias RF power having different frequencies by applying additional power other than the bias RF power.

The additional power supply may include direct current (DC) power or alternating current (AC) power as long as the effect thereof is obtained without restricting the RF frequency.

In addition, when other additional power supplies than the source and bias power supplies are combined, a pulsing technique of adjusting the application and the cut-off of electric power of each power supply may be applied.

In this case, when the pulsing is performed, a case in which low power is supplied rather than completely turning off the power source in a power source OFF operation may be included and combined together with the effect thereof.

The above-described examples have been described in detail in Examples 1 to 21 and may be combined together with various advanced pulsing techniques.

FIG. 3 is a schematic diagram illustrating a result deposited by the atomic layer deposition method of filling the gap of the semiconductor structure with the high aspect ratio according to one embodiment of the present invention.

FIG. 3A illustrates a state in which deposition is not performed on a semiconductor structure with a high aspect ratio, FIG. 3B illustrates a state in which source RF power is applied to the semiconductor structure with the high aspect ratio through the ALD method, FIG. 3C illustrates a state in which bias RF power is applied to the semiconductor structure with the high aspect ratio through the ALD method, FIG. 3D illustrates a state in which high bias RF power is applied to the semiconductor structure with the high aspect ratio through the ALD method, and FIG. 3E illustrates a state in which pulsed bias RF power is applied to the semiconductor structure with the high aspect ratio through the ALD method.

Referring to FIG. 3, it can be seen that when the pulsed bias RF power is applied, a void, a seam, or an overhang is not formed, and an internal gap is filled.

Therefore, according to the atomic layer deposition method of filling the gap of the semiconductor structure with the high aspect ratio according to one embodiment of the present invention, it is possible to remove an overhang and perform improved gap-filling deposition without void and a seam.

An atomic layer deposition method of filling a gap of a semiconductor structure with a high aspect ratio according to another embodiment of the present invention will be described.

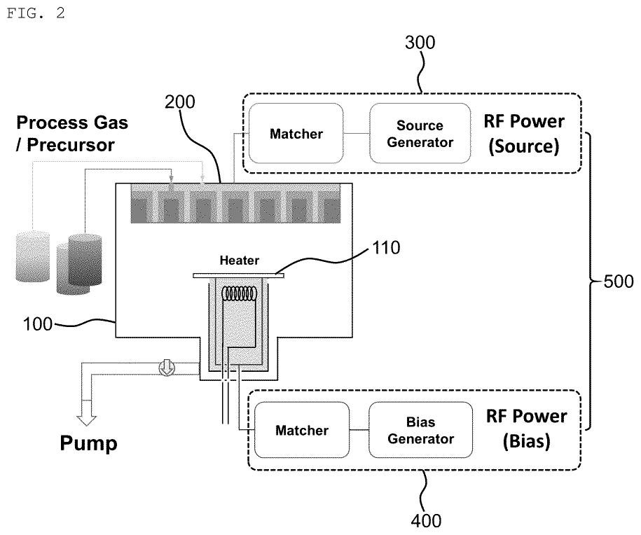

FIG. 2 is a schematic diagram illustrating an atomic layer deposition device for filling the gap of the semiconductor structure with the high aspect ratio according to one embodiment of the present invention.

Referring to FIG. 2, the atomic layer deposition device for filling the gap of the semiconductor structure with the high aspect ratio according to one embodiment of the present invention may include a reaction chamber 100 for forming a constant reaction space, a substrate mounting table 110 which is installed inside the reaction chamber and on which a substrate is placed, a gas spray unit 200 for spraying a precursor and a process gas onto the substrate mounting table, a source RF plasma generation unit 300 installed above the reaction chamber and connected to the substrate mounting table, a bias RF power source unit 400 installed under the reaction chamber, connected to the substrate mounting table, and for supplying bias RF power, and a control unit 500 for controlling the ON-OFF of source RF power of the source RF plasma generation unit and bias RF power of the bias RF power source unit.

In this case, the source RF plasma generation unit may include an RF power source for supplying impedance-matched RF power to a plasma generation unit and a pulse RF connected between a gas supplier and the RF power source.

The ALD device according to one embodiment of the present invention is characterized that the pulse RF for receiving a signal supplied from a bias RF power source and converting the signal into a pulse is installed between the bias RF power source unit connected to the substrate mounting table and a bias matcher.

In this case, the bias RF power source unit may include the bias RF power source for supplying the impedance-matched bias RF power to the substrate mounting table and the pulse RF connected between the substrate mounting table and the bias RF power source.

In the atomic layer deposition device according to the embodiment of the present invention, the pulse RF for receiving the signal supplied from the bias RF power source and converting the signal into the pulse is installed between the bias RF power source connected to the substrate mounting table and the bias matcher.

As described above, when the pulse RF is installed, the RF power output from the bias RF power source is converted into the pulse and applied to the substrate mounting table via the bias matcher.

The bias RF power applied to the substrate mounting table periodically becomes a bias RF ON state or a bias RF OFF state by the pulse RF.

In this case, in the bias RF ON state, ions are momentarily accelerated, and the amount of ions entering a substrate w increases, and in the bias RF OFF state, the ions are not accelerated, and thus there is almost no amount of ions accelerated to the substrate w.

In the bias RF ON state, high accelerated ions enter inside high aspect ratio structure gap of the substrate w and thus deposition is actively performed.

On the other hand, in the bias RF OFF state, there is almost no amount of ions accelerated to the substrate w.

Hereinafter, the present invention will be described in more detail through manufacture examples and experimental examples. These manufacture examples and experimental examples are merely for exemplarily describing the present invention, and the scope of the present invention is not limited by these manufacture examples and experimental examples.

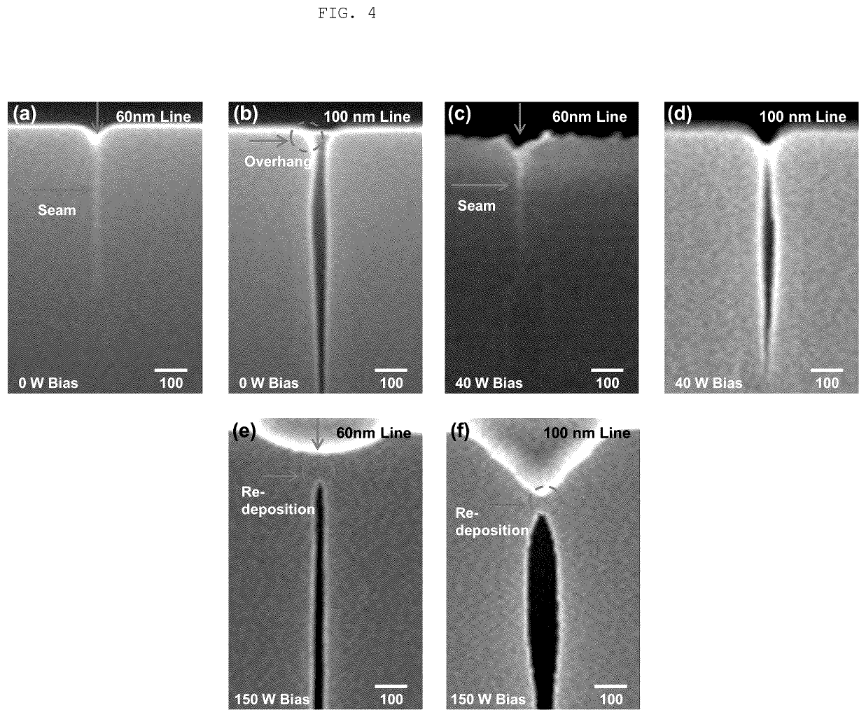

### Manufacture Example 1: Manufacturing Semiconductor Device with High Aspect Ratio in which Gap is Filled by Atomic Layer Deposition Method of Filling Gap of Semiconductor Structure with High Aspect Ratio [See FIG. 5]

First, a semiconductor substrate on which patterns with gaps of 60 nm and 100 nm were formed were put into a reaction chamber.

Next, a DIPAS precursor gas was injected into a semiconductor substrate in which the gaps were formed for 1 second under a condition in which a chamber pressure was 2 Torr and a substrate temperature was 200° C., and the precursor gas was adsorbed onto the substrate.

Next, a purging that discharges a non-adsorbed precursor was performed for 5 seconds.

Next, each of process gases consisting of Ar gas and O₂ gas materials was supplied to an inside of the reaction chamber at a flow rate of 500 sccm, plasma was generated in a reaction space by supplying power to an upper electrode at 60 MHz RF power with source RF power of 1000 W, and pulsed power was applied to a lower electrode at 400 kHz RF power with bias RF power of 40 W.

In this case, a specific control method of turning on and off the pulsed bias RF power will be described in detail in [Experimental Example 2] below.

Next, a purging that discharges a non-adsorbed precursor was performed for 5 seconds.

The process was performed in the form of one cycle, and in particular, a semiconductor device with a high aspect ratio in which the gap was filled was manufactured by controlling the ON-OFF of the source RF power and the pulsed bias RF power.

### Manufacture Example 2

This was an example applied from Manufacture Example 1, and Examples 1 to 21 showed that other RF control methods based on bias pulsed power were applied by further including an additional pulse RF power supply to present an improved process in a state in which the effect thereof was combined.

### Example 1

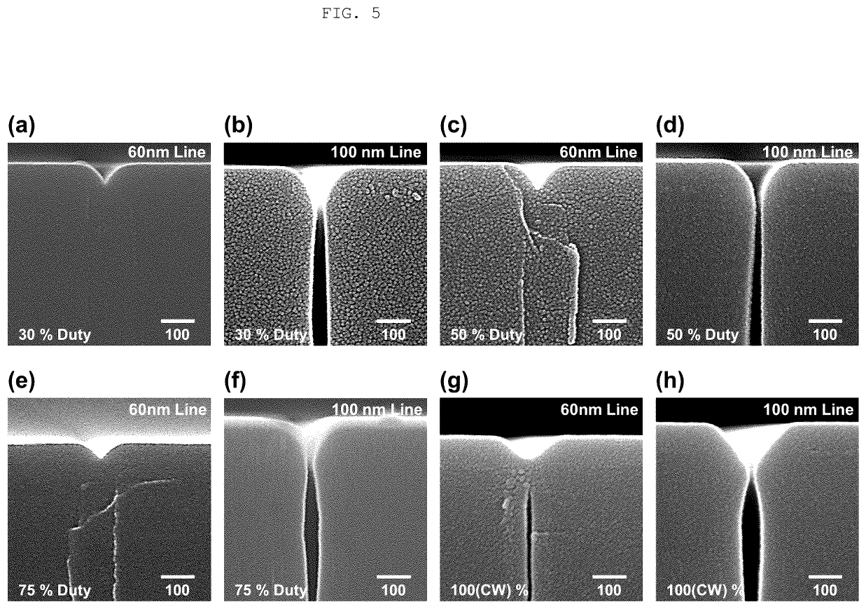

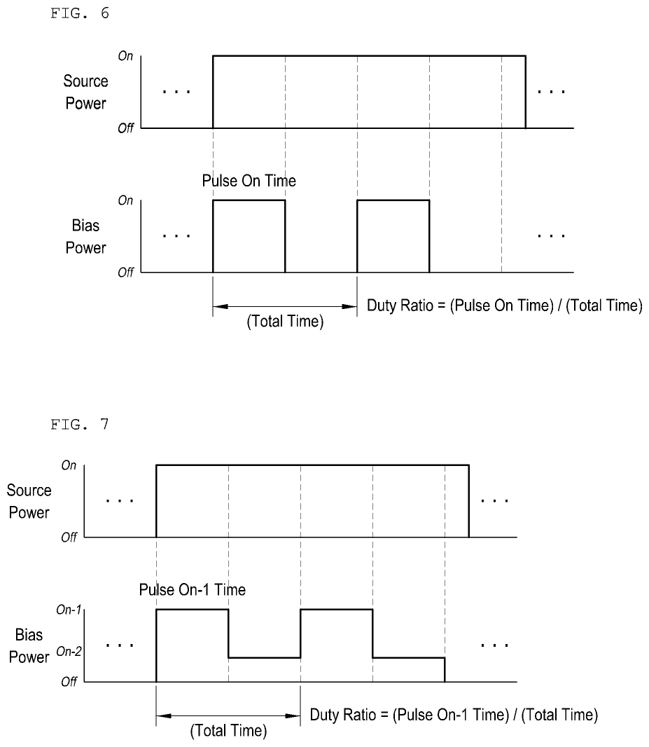

FIG. 6 is a graph illustrating a result of Example 1.

Referring to FIG. 6, the pulsed source RF power was identically and continuously applied at the constant power of −50 V as a role of generating plasma, and the pulsed bias RF power was applied at an intensity at which a bias could be generated so that a pulse duty ratio was in a range of 1 to 100% upon ON-OFF.

The pulse duty ratio is a pulse ON time/a total time.

### Example 2

FIG. 7 is a graph illustrating a result of Example 2.

Referring to FIG. 7, the pulsed source RF power was identically and continuously applied at a constant intensity as a role of generating plasma, and the pulsed bias RF power was continuously applied and was repeatedly adjusted from a power intensity of −50 V at which a bias could be generated to a power intensity of −50 V or less at which the bias could be generated.

### Example 3

FIG. 8 is a graph illustrating a result of Example 3.

Referring to FIG. 8, the pulsed source RF power was identically and continuously applied at a constant intensity as a role of generating plasma, the pulsed bias RF power was applied at an intensity at which a bias could be generated so that a pulse duty ratio was in a range of 1 to 100% upon ON-OFF, and power through RF power supply was identically and continuously applied at an intensity at which the effect according to an additional frequency could be obtained.

### Example 4

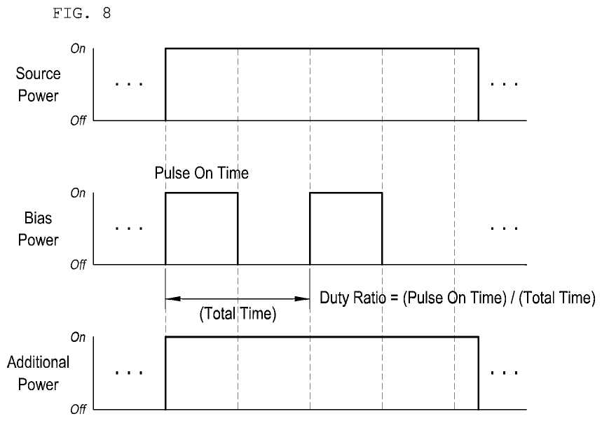

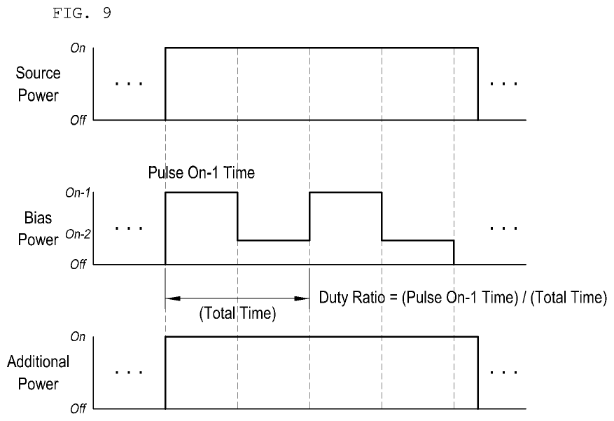

FIG. 9 is a graph illustrating a result of Example 4.

Referring to FIG. 9, the pulsed source RF power was identically and continuously applied at a constant intensity as a role of generating plasma, the pulsed bias RF power was continuously applied and was repeatedly adjusted from a power intensity of −50 V at which a bias could be generated to a power intensity of −50 V or less at which the bias could be generated, and power through RF power supply was identically and continuously applied at an intensity at which the effect according to an additional frequency could be obtained.

### Example 5

FIG. 10 is a graph illustrating a result of Example 5.

Referring to FIG. 10, the pulsed source RF power was applied at a constant power intensity of −50 V as a role of generating plasma so that a pulse duty ratio was in a range of 1 to 100% upon ON-OFF, and the pulsed bias RF power was simultaneously applied at an intensity of −50 V at which a bias could be generated so that the pulse duty ratio was in a range of 1 to 100% upon ON-OFF.

At this time, the pulsed source RF power and the pulsed bias RF power were simultaneously applied and simultaneously cut off.

### Example 6

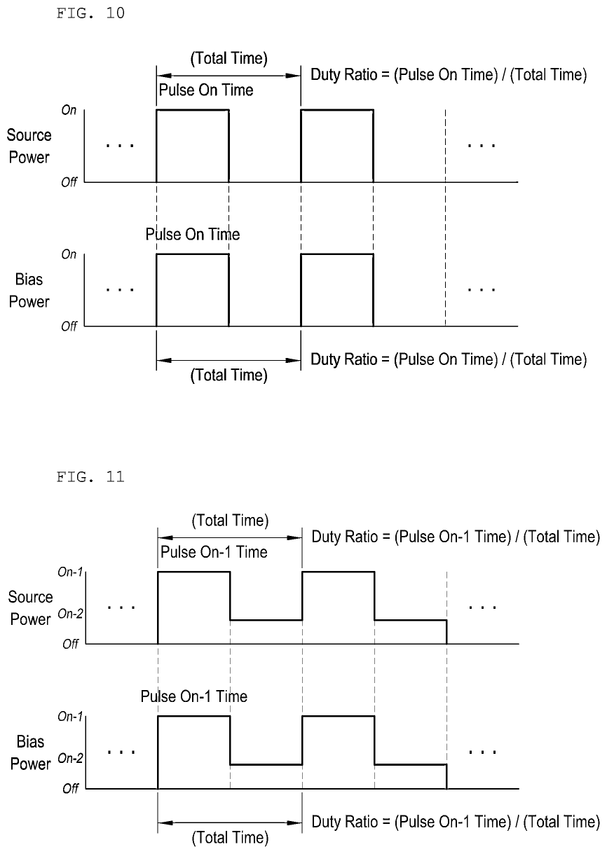

FIG. 11 is a graph illustrating a result of Example 6.

Referring to FIG. 11, the pulsed source RF power was identically and continuously applied at a constant power intensity of −50 V as a role of generating plasma and was repeatedly adjusted from a high power intensity of −50 V at which a source could be generated to a power intensity of −50 V or less at which the source could be generated, and the pulsed bias RF power was continuously applied and was repeatedly adjusted from a high power intensity of −50 V at which a bias could be generated to a low power intensity of −50 V or less at which the bias could be generated.

At this time, the pulsed source RF power and the pulsed bias RF power were simultaneously applied at high powers and simultaneously applied at low powers.

### Example 7

FIG. 12 is a graph illustrating a result of Example 7.

Referring to FIG. 12, the pulsed source RF power was applied at a constant power intensity of −50 V as a role of generating plasma so that a pulse duty ratio was in a range of 1 to 100% upon ON-OFF, the pulsed bias RF power was applied at the constant power intensity of −50 V as a role of generating plasma so that the pulse duty ratio was in a range of 1 to 100% upon ON-OFF, and the added plasma power was applied at the constant power intensity of −50 V as a role of generating plasma so that the pulse duty ratio was in a range of 1 to 100% upon ON-OFF.

The pulsed source RF power, the pulsed bias RF power, and the added pulse RF power were simultaneously applied and simultaneously cut off.

### Example 8

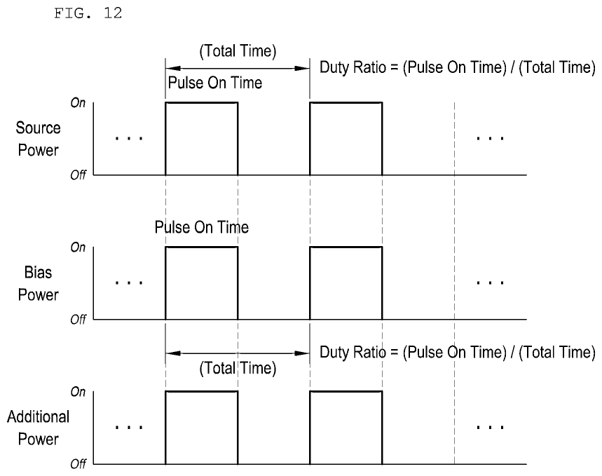

FIG. 13 is a graph illustrating a result of Example 8.

Referring to FIG. 9, the pulsed source RF power was identically and continuously applied at a constant power intensity of −50 V as a role of generating plasma and was repeatedly adjusted from a power intensity of −50 V at which the source could be generated to a power intensity of −50 V or less at which the source could be generated, the pulsed bias RF power was continuously applied and was adjusted from the power intensity of −50 V at which a bias could be generated to the power intensity of −50 V or less at which the bias could be generated, and the added plasma power was applied by being repeatedly adjusted at the constant power of −50 V as a role of generating plasma. The pulsed source RF power, the pulsed bias RF power, and the added pulse RF power were simultaneously applied at high powers and simultaneously applied at low powers.

### Example 9

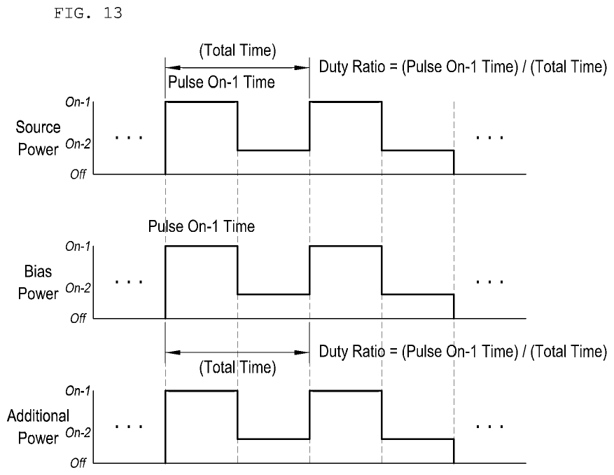

FIG. 14 is a graph illustrating a result of Example 9.

Referring to FIG. 14, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF.

When the pulsed source RF power was applied, the pulsed bias RF power was cut off, and when the pulsed source RF power was cut off, the pulsed bias RF power was applied.

### Example 10

FIG. 15 is a graph illustrating a result of Example 10.

Referring to FIG. 15, the pulsed source RF power was identically and continuously applied at a constant power intensity of −50 V as a role of generating plasma and was repeatedly adjusted from the power intensity of −50 V at which a source could be generated to a power intensity of −50 V or less at which the source could be generated, the pulsed bias RF power was continuously applied and was adjusted from a high power intensity at which a bias could be generated to a low power intensity at which the bias could be generated, and an added plasma power was applied by being repeatedly adjusted at the constant power intensity as a role of generating plasma.

When the pulsed source RF power was applied at a high intensity, the pulsed source RF power was applied at a low intensity, and when the pulsed source RF power was applied at the low intensity, the pulsed source RF power was applied at the high intensity.

### Example 11

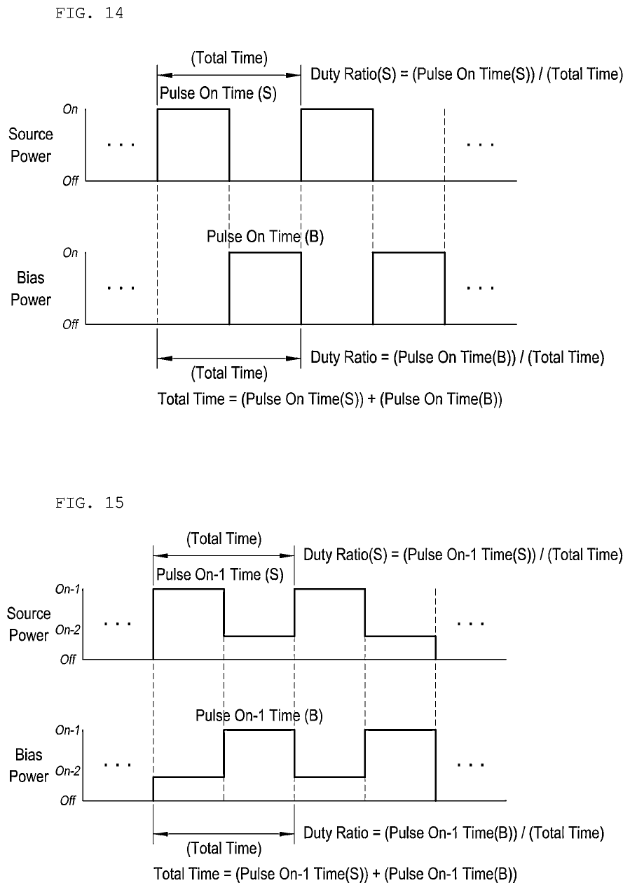

FIG. 16 is a graph illustrating a result of Example 11.

Referring to FIG. 16, the pulsed source RF power was applied at a constant power intensity of −50 V as a role of generating plasma so that a pulse duty ratio was in a range of 1 to 100% upon ON-OFF, the pulsed bias RF power was applied at the constant power intensity of −50 V as a role of generating plasma so that the pulse duty ratio was in a range of 1 to 100% upon ON-OFF, and an added pulse RF power was applied at a constant power intensity as a role of generating additional power so that the pulse duty ratio was in a range of 1 to 100% upon ON-OFF.

At this time, the sum of duty ratios of the source RF power supply, the bias RF power supply, and the added RF power supply is 100%.

When the pulsed source RF power was applied, the pulsed bias RF power and the added pulse RF power were simultaneously cut off, when the pulsed bias RF power was applied, the pulsed source RF power and the added pulse RF power were simultaneously cut off, applied, and simultaneously cut off, and when the added pulse RF power was applied, the pulsed source RF power and the pulsed bias RF power were simultaneously cut off.

### Example 12

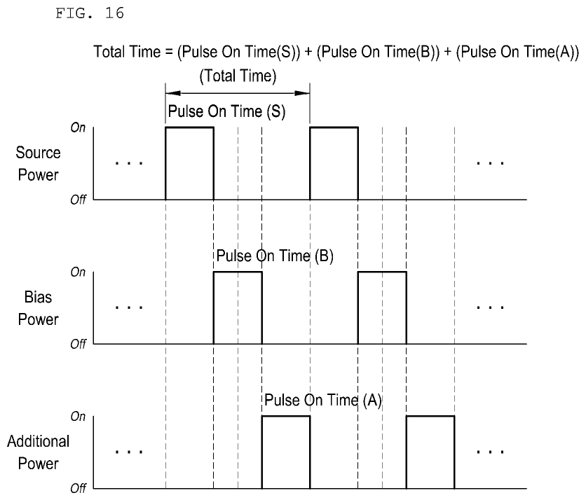

FIG. 17 is a graph illustrating a result of Example 12.

Referring to FIG. 17, the pulsed source RF power was identically and continuously applied at a constant power intensity of −50 V as a role of generating plasma and was repeatedly adjusted from a high power intensity of −50 V at which a source could be generated to a low power intensity of −50 V or less at which the source could be generated, the pulsed bias RF power was continuously applied and was adjusted from the high power intensity of −50 V at which a bias could be generated to the low power intensity of −50 V or less at which the bias could be generated, and the added plasma power was continuously applied at a constant power intensity as a role of generating additional power and was repeatedly adjusted from the high power intensity of −50 V at which plasma could be generated to the low power intensity of −50 V or less at which the plasma could be generated.

The sum of duty ratios of the source, bias, and added RF power supplies based on that the power supply with a high intensity was turned on is 100% (one cycle of pulse).

When the pulsed source RF power was applied at the high intensity, the pulsed bias RF power and the added pulse RF power were applied at the low intensities, when the pulsed bias RF power was applied at the high intensity, the pulsed source RF power and the added pulsed RF power were applied at the low intensities, and when the added pulse RF power was applied at the high intensity, the pulsed source RF power and the pulsed bias RF power were applied at the low intensities.

### Example 13

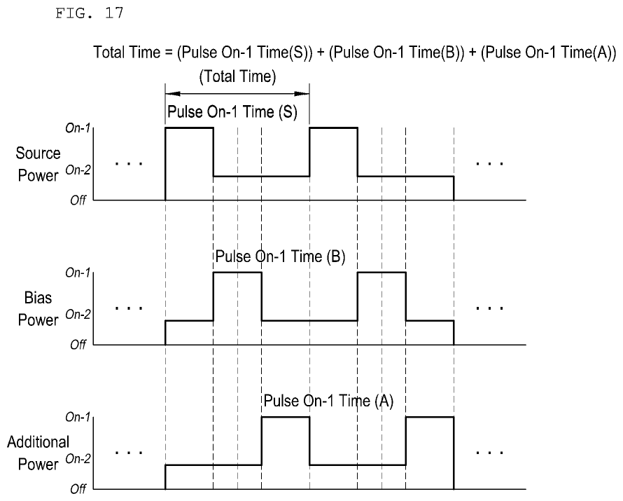

FIG. 18 is a graph illustrating a result of Example 13.

Referring to FIG. 18, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF.

When the pulsed source RF power was applied, the pulsed bias RF power was applied to overlap the pulsed source RF power for a time for which an ON time of the pulse duty ratio was in a range of 1 to 100%.

### Example 14

FIG. 19 is a graph illustrating a result of Example 14.

Referring to FIG. 19, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF. Both the pulsed source RF power and the pulsed bias RF power may have Off-time-1 (separation time) during the pulse duty ratio. The separation time is a section in which both the source RF power and the pulsed bias RF power are turned off. In addition, both the pulsed source RF power and the pulsed bias RF power may have Off-time-2. The Off-time-2 is a section in which both the source RF power and the pulsed bias RF power are turned off.

### Example 15

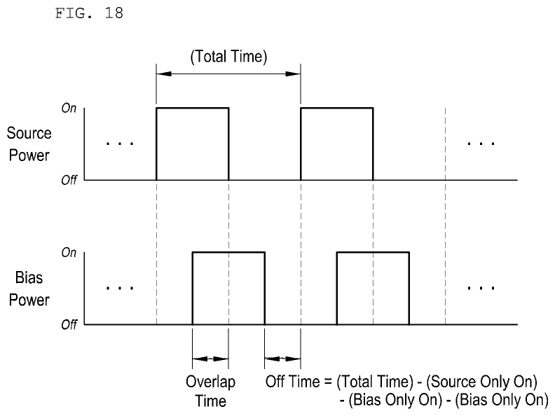

FIG. 20 is a graph illustrating a result of Example 15.

Referring to FIG. 20, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF. The pulsed source RF power is first turned on during the pulse duty ratio of 1 to 99% and then overlaps a bias power pulse in some sections, and the pulsed source RF power and the bias power pulse are also turned off at the same time. When the pulsed source RF power was applied, the pulsed bias RF power was applied to overlap the pulsed source RF power for a time for which an ON time of the pulse duty ratio was in a range of 1 to 100%.

### Example 16

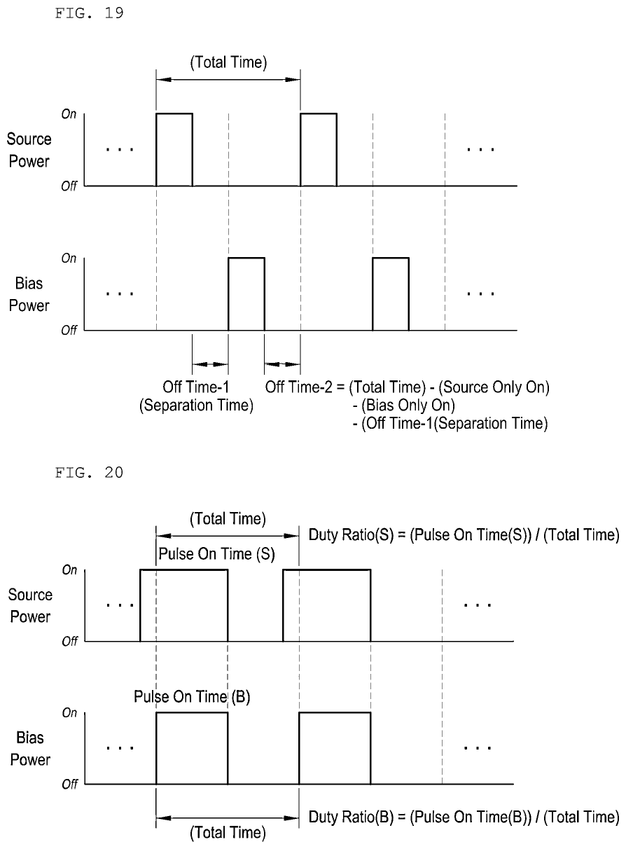

FIG. 21 is a graph illustrating a result of Example 16.

Referring to FIG. 21, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF. When the pulsed source RF power is applied, the pulsed source RF power may be turned on during the pulse duty ratio of 1 to 100% even after the bias power is turned off. In this case, in Examples 15 and 16, the remaining sections excluding a section in which the ON times of the pulse duty ratio do not overlap were performed under the same experimental condition.

### Example 17

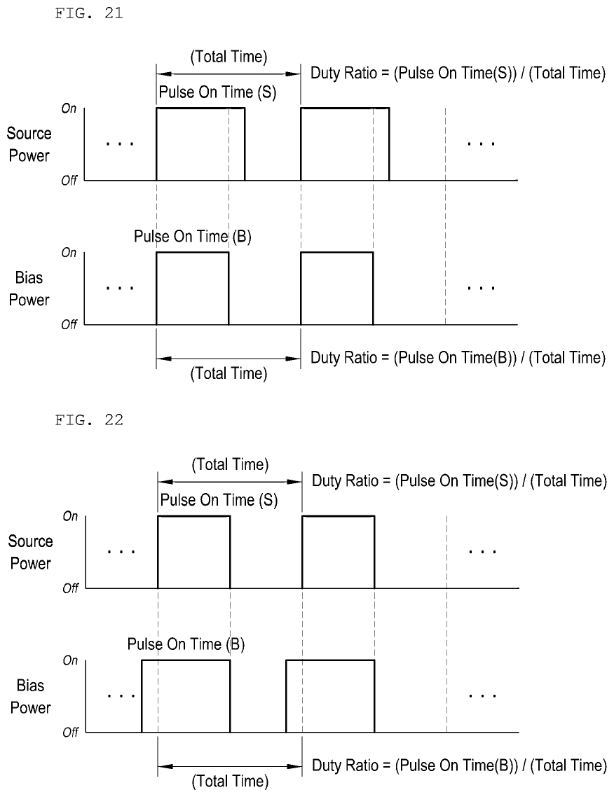

FIG. 22 is a graph illustrating a result of Example 17.

Referring to FIG. 22, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF. When the pulsed source RF power is applied, the pulsed bias RF power may be first turned on during the pulse duty ratio of 1 to 99%. Therefore, in some sections, a pulse of the source RF power and a pulse of the bias RF power overlap each other and are also turned off at the same time.

### Example 18

FIG. 23 is a graph illustrating a result of Example 18.

Referring to FIG. 23, the pulsed source RF power was applied at a constant power intensity of −50 V as a role of generating plasma so that a pulse duty ratio was in a range of 1 to 100% upon ON-OFF, and the pulsed bias RF power was applied at the constant power intensity of −50 V as a role of generating plasma so that the pulse duty ratio was in a range of 1 to 100% upon ON-OFF. When the pulsed source RF power was applied, the pulsed bias RF power was independently applied additionally for a time for which the pulse duty ratio was 1 to 100% after the pulse of the source RF power was ended. In this case, in Examples 17 and 18, the remaining sections excluding a section in which the ON times of the pulse duty ratio do not overlap were performed under the same experimental condition.

### Example 19

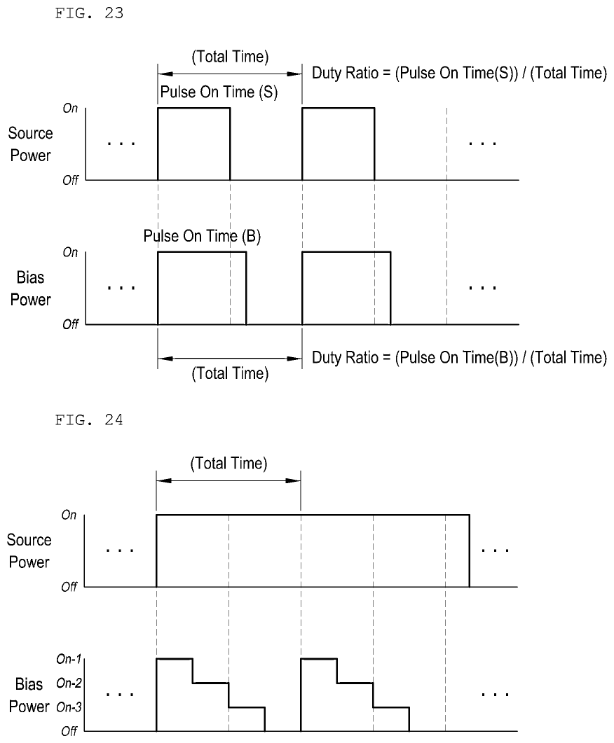

FIG. 24 is a graph illustrating a result of Example 19.

Referring to FIG. 6, the pulsed source RF power was identically and continuously applied at a constant power intensity of −50 V as a role of generating plasma, and the pulsed bias RF power was applied at the constant power intensity of −50 V as a role of generating plasma so that the pulse duty ratio was in a range of 1 to 100% upon ON-OFF.

For an operation intensity of the bias RF power, the pulsed bias RF power was continuously applied and was adjusted to a high power intensity of −50 V at which a bias could be generated (On-1), then adjusted from the high power intensity of −50 V at which the bias could be generated to a medium power intensity at which the bias could be generated (On-2), and adjusted from the medium power intensity at which the bias could be generated to a power intensity lower than the medium power intensity at which the bias could be generated (On-3).

### Example 20

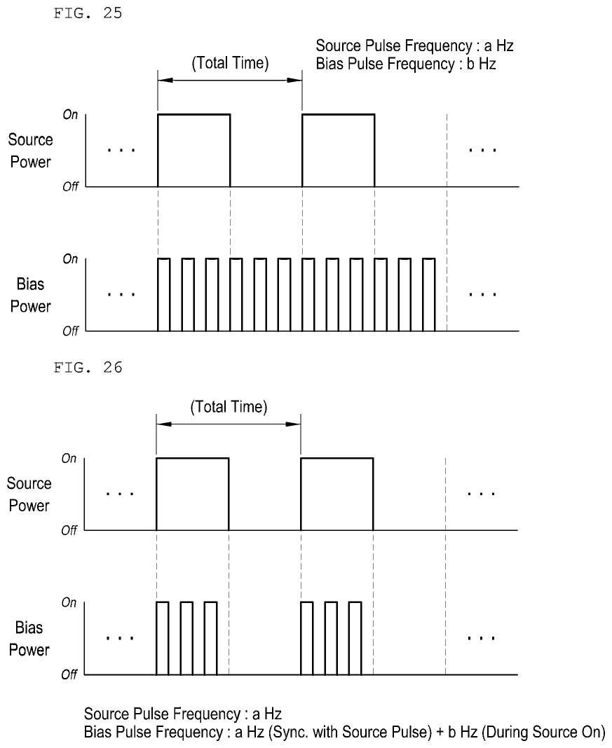

FIG. 25 is a graph illustrating a result of Example 20.

Referring to FIG. 25, the pulsed source RF power was applied at a constant power intensity of −50 V and at a pulse frequency of 13.56 to 130 MHz as a role of generating plasma so that a pulse duty ratio was in a range of 1 to 100% upon ON-OFF, and the pulsed bias RF power was applied at the constant power intensity of −50 V and the pulse RF of 13.56 to 130 MHz as a role of generating plasma so that the pulse duty ratio was in a range of 1 to 100% upon ON-OFF. In this case, a bias pulse frequency may be higher than a source pulse frequency.

### Example 21

FIG. 26 is a graph illustrating a result of Example 21.

Referring to FIG. 26, the pulsed source RF power was applied at a constant power intensity of −50 V and a pulse frequency of 13.56 to 130 MHz as a role of generating plasma so that a pulse duty ratio was in a range of 1 to 100% upon ON-OFF, and the pulsed bias RF power was applied at the constant power intensity of −50 V and the pulse RF of 13.56 to 130 MHz as a role of generating plasma so that the pulse duty ratio was in a range of 1 to 100% upon ON-OFF. In this case, a bias pulse frequency may be n times higher than a source pulse frequency. When the pulsed source RF power was cut off, the pulsed bias RF power was also cut off.

### Experimental Example 1: Result of Performing ALD for 300 Cycles According to Bias Power Intensity

FIG. 4 is scanning electron microscope (SEM) images representing a result of Experimental Example 1.

FIG. 4 is the SEM images as a result of performing the ALD for 300 cycles in order to check the use of the ALD according to the bias power intensity.

Like the results illustrated in FIGS. 4A and 4B, as an experimental result, it can be seen that when the ALD was performed without bias power an overhang was formed at pattern top of a high aspect ratio structure, and a seam was formed in a 60 nm line pattern.

FIG. 4B is a view illustrating a result when gap-filling is being performed on a 100 nm line pattern, and it can be seen that the overhang was formed at the pattern top.

Experiments in FIGS. 4C and 4D show a result of performing the ALD after applying a bias of 40 W that is a relatively lower bias power intensity.

As illustrated in FIG. 4C, it can be seen that the seam was formed in the 60 nm line pattern.

FIG. 4D illustrates a state in which the gap-filling was insufficiently performed on the 100 nm line pattern, and it can be seen that the overhang was formed.

Referring to FIGS. 4C and 4D, results of FIGS. 5G and 5H when the process was performed for 500 cycles are illustrated, respectively.

As a result, it can be seen that a very large seam is shown in the 60 nm line, and a void is shown in the 100 nm line.

In addition, FIGS. 4E and 4F illustrate a result of performing the ALD after applying a bias of 150 W that is relatively higher bias power, and it can be seen that not only the overhang was formed, but also a deposited material was re-deposited due to the high bias to block an upper pattern and thus a very severe void was formed.

Therefore, through Experimental Example 1, it is preferable that the relatively lower bias power with the intensity of 40 W is applied, and as described above, it was confirmed that a case in which there was a bias was further advantageous for the gap-filling than a case in which there was no bias.

However, it can be seen that there is the limitation to this, and the need for an additional control device using bias pulsed is shown.

In addition, as in the example of 150 W, when the bias is rather too high, the limitation is reliably shown based on that the bias works through the phenomenon in which the deposited material at the pattern top side is re-deposited due to the high bias when the bias is rather too high.

### Experimental Example 2: Result of Performing ALD According to Pulse Duty Ratio of Bias Pulse

FIG. 5 is SEM images representing a result of Experimental Example 2.

FIG. 5 illustrates a result showing an example in which the ALD is used according to the pulse duty ratio of the bias pulse.

Referring to FIG. 5, it can be seen that in FIGS. 5A to 5F, further improved gap-filling than the gap-filling in FIGS. 5G and 5H was performed by using the bias pulse.

In addition, in a direction of decreasing the pulse duty ratio, in the case of the 100 nm line, FIGS. 5E and 5F illustrate a case in which the pulse duty ratio is 75%, FIGS. 5C and 5D illustrate a case in which the pulse duty is 50%, and FIGS. 5A and 5B illustrates a case in which the pulse duty ratio is 30%, and it can be seen that the excellent gap-filling effect can be obtained as the pulse duty ratio decreases to 30%, and since charging decreased and diffusion increased, reactants (gas particles) deeply entered an inside of the pattern and at the same time, bias power was applied, and thus deposition was performed as the opening of the gap was opened perpendicularly.

In addition, referring to FIGS. 5H, 5F, 5D, and 5B illustrating a case in which a width of the gap is 100 nm, it can be seen that as the pulse duty ratio decreases, a portion of an upper portion of the formed pattern was blocked, and an insulating film (SiO₂) was vertically deposited on an internal wall surface of the gap even in a negative bow profile (see a schematic diagram such as FIG. 3A), and thus the gap-filling was well performed.

The manufacture in FIG. 5 is a result according to various pulse duty ratios under the condition of Manufacture Example 1.

The above description of the present invention is for illustrative purpose, and those skilled in the art to which the present invention pertains will be able to understand that the present invention may be easily modified in other specific forms without changing the technical spirit or essential features thereof. Therefore, it should be understood that the above-described embodiments are illustrative and not restrictive in all respects. For example, each component described form may be implemented separately, and likewise, in a singular components described as being implemented separately may also be implemented in a combined form.

According to the atomic layer deposition method of filling the gap of the semiconductor structure with the high aspect ratio according to one embodiment of the present invention, it is possible to remove the overhang at the pattern top at the same time as deposition and perform the gap-filling to remove the void and the seam by improving the bottom-up deposition in the high aspect ratio of 40:1 or more.

Therefore, since the separate thermal treatment process can be omitted and a complicated process such as deposition-etching-deposition is not required, it is possible to increase the efficiency of the manufacture of the semiconductor device.

In addition, it is also possible to perform the gap-filling on the high aspect ratio structure with a negative bow profile that it is difficult to perform the gap-filling by the conventional ALD method. Therefore, the present invention may also be applied to a next-generation device requiring various structures.

In addition, the present invention is characterized that the bias power is used to remove the overhang and the bias power is pulsed.

It is possible to effectively remove the overhang at the pattern top of the high aspect ratio structure through the pulsing of the bias, remove the void and the seam inside the structure, and perform the bottom-up process in which deposition is possible from a bottom to a top of the structure.

It should be understood that the effects of the present invention are not limited to the above-described effects and include all effects inferable from the configuration of the invention described in the detailed description or claims of the present invention.

The scope of the present invention is defined by the claims to be described below, and all changes or modifications derived from the meaning and scope of the claims and equivalent concepts thereof should be construed as being included in the scope of the present invention.

DESCRIPTION OF REFERENCE NUMERALS

| | |
|---|---|
| 100: chamber | 110: substrate mounting table |
| 200: gas spray unit | 300: source RF plasma generation unit |
| 400: bias RF power source unit | |
| 500: control unit | |

What is claimed is:

1. An atomic layer deposition method of filling a gap of a semiconductor structure with a high aspect ratio, the method comprising:
a first operation of putting a substrate in which the gap is formed into a reaction chamber;
a second operation of injecting a precursor gas into the substrate in which the gap is formed and adsorbing the precursor gas onto the substrate;
a third operation of supplying a process gas to an inside of the chamber, generating plasma in a reaction space above the substrate by applying pulsed or non-pulsed source RF power, and applying pulsed bias RF power; and
a fourth operation of controlling the ON-OFF ratio of the pulsed or non-pulsed source RF power and the pulsed bias RF power.

2. The method of claim 1, further comprising an operation of purging the chamber between the second operation and the third operation.

3. The method of claim 1, further comprising, after the fourth operation, an operation of purging the chamber.

4. The method of claim 1, wherein in the fourth operation, the pulsed or non-pulsed source RF power is continuously applied at the same intensity, and the pulsed bias RF power is applied in ON-OFF states.

5. The method of claim 4, wherein when the pulsed bias RF power is turned on or off, a pulse duty ratio is in a range of 1 to 99%.

6. The method of claim 1, wherein in the fourth operation, the pulsed or non-pulsed source RF power is continuously applied at the same intensity, and the pulsed bias RF power is continuously applied and has an adjustable intensity.

7. The method of claim 1, wherein in the fourth operation, the pulsed or non-pulsed source RF power is continuously applied and has an adjustable intensity, and the pulsed bias RF power is continuously applied and has an adjustable intensity.

8. The method of claim 1, wherein in the fourth operation, the pulsed or non-pulsed source RF power is applied in ON-OFF states, and the pulsed bias RF power is applied in ON-OFF states.

9. The method of claim 8, wherein in the fourth operation, the pulsed or non-pulsed source RF power and the pulsed bias RF power are simultaneously applied and simultaneously cut off.

10. The method of claim 8, wherein in the fourth operation, when the pulsed or non-pulsed source RF power is applied, the pulsed bias RF power is cut off, and when the pulsed source RF power is cut off, the pulsed bias RF power is applied.

11. The method of claim 1, wherein in the third operation, the bias RF power is applied in a range of 5 to 500 W.

12. The method of claim 1, wherein in the fourth operation, when a deposit generated by a deposition process gas is filled inside the gap, the application of the pulsed source RF power and the pulsed bias RF power is stopped.

13. The method of claim 1, wherein in the third operation, power is applied by further including an additional power supply other than the bias RF power.

14. The method of claim 1, wherein the atomic layer deposition method of filling the gap of the semiconductor structure with the high aspect ratio is performed at a temperature of 0 to 500° C.

15. An atomic layer deposition device for filling a gap of a semiconductor structure with a high aspect ratio, the atomic layer deposition device comprising:
a reaction chamber in which a constant reaction space is formed;
a substrate mounting table which is installed inside the reaction chamber and on which a substrate is placed;
a gas spray unit configured to spray a precursor and a process gas onto the substrate mounting table;
a source RF plasma generation unit installed above the reaction chamber and connected to the gas spray unit;
a bias RF power source unit installed under the reaction chamber, connected to the substrate mounting table, and configured to supply bias RF power; and
a control unit configured to control the ON-OFF of source RF power of the source RF plasma generation unit and bias RF power of the bias RF power source unit.

16. The atomic layer deposition device of claim 15, wherein the source RF plasma generation unit includes:
an RF power source configured to supply impedance-matched RF power to a plasma generation source; and
a pulse RF connected between a gas supply unit and the RF power source.

17. The atomic layer deposition device of claim 15, wherein the bias RF power source unit includes:
a bias RF power source configured to supply impedance-matched bias RF power to the substrate mounting table; and
a pulse RF connected between the substrate mounting table and the bias RF power source.
